(19) United States
(12) Patent Application Publication
(10) Pub. No.: US 2026/0305311 A1
(43) Pub. Date: Oct. 1, 2026

(54) SEMICONDUCTOR DEVICES, METHODS FOR FORMING THE SAME, AND MEMORY SYSTEMS

(71) Applicant: Yangtze Memory Technologies Co., Ltd., Wuhan (CN)

(72) Inventors: Baoqing Sun, Wuhan (CN); Xu Hou, Wuhan (CN); Yu Wang, Wuhan (CN)

(21) Appl. No.: 19/425,039

(22) Filed: Dec. 18, 2025

(30) Foreign Application Priority Data
Apr. 1, 2025 (CN) 202510405585.3

(51) Int. Cl. H10W 20/41; H10B 12/00; H10D 1/68; H10D 80/30; H10W 20/00

(52) U.S. Cl. CPC H10W 20/435; H10B 12/033; H10B 12/315; H10D 1/716; H10D 80/30; H10W 20/056

(57) ABSTRACT

An example semiconductor device includes: a first semiconductor structure including capacitor structures, a first electrode plate and a first contact structure, the first electrode plate is coupled with the capacitor structures; a second semiconductor structure bonded to the first semiconductor structure; a conductive structure extending along a first direction and arranged at intervals along a second direction, the conductive structure located on a side of the first semiconductor structure away from the second semiconductor structure; the conductive structure including first conductive structures coupled with the second semiconductor structure, and a plurality of second conductive structures between adjacent ones of the first conductive structures and coupled to the first electrode plate; the first electrode plate is located between the second conductive structures and the capacitor structures; the first contact structure extends along a third direction and is located on a side of the first electrode plate along the first direction.

### CROSS-REFERENCE TO RELATED APPLICATIONS

This application claims priority to and the benefit of Chinese Patent Application 202510405585.3, filed on Apr. 1, 2025, which is hereby incorporated by reference in its entirety.

### TECHNICAL FIELD

Examples of the present disclosure relate to the field of semiconductor technologies, and in particular, to semiconductor devices, methods for forming the same, and memory systems.

### BACKGROUND

With the development of semiconductor processes, the feature size of semiconductor devices is increasingly reduced, and the integration level is also increasingly high.

### BRIEF DESCRIPTION OF THE DRAWINGS

FIG. 1 is a schematic cross-sectional view of a semiconductor device according to an example of the present disclosure.

FIG. 2 is a schematic circuit connection diagram of a 1T1C architecture according to an example of the present disclosure.

FIG. 3 is a schematic cross-sectional view of a semiconductor device according to an example of the present disclosure.

FIG. 4A is a first schematic diagram of a structural form of a capacitor structure according to an example of the present disclosure.

FIG. 4B is a second schematic diagram of a structural form of a capacitor structure according to an example of the present disclosure.

FIG. 5 is a schematic perspective view of a semiconductor device according to an example of the present disclosure.

FIG. 6 is a first schematic top view of a semiconductor device according to an example of the present disclosure.

FIG. 7 is a second schematic top view of a semiconductor device according to an example of the present disclosure.

FIG. 8 is a schematic cross-sectional view along AA′ direction in FIG. 6.

FIG. 9 is a third schematic top view of a semiconductor device according to an example of the present disclosure.

FIG. 10 is a flowchart of a method for forming a semiconductor device according to an example of the present disclosure.

FIG. 11 is a first schematic top view in a process of forming a semiconductor device according to an example of the present disclosure.

FIG. 12 is a schematic cross-sectional view along AA′ direction in FIG. 11.

FIG. 13 is a second schematic top view in a process of forming a semiconductor device according to an example of the present disclosure.

FIG. 14 is a schematic cross-sectional view along AA′ direction in FIG. 13.

FIG. 15 is a third schematic top view in a process of forming a semiconductor device according to an example of the present disclosure.

FIG. 16 is a schematic cross-sectional view along AA′ direction in FIG. 15.

FIG. 17A is a schematic composition block diagram of an example system according to an example of the present disclosure.

FIG. 17B is a schematic composition diagram of an example system according to an example of the present disclosure.

FIG. 18A is a schematic composition block diagram of an example solid state drive (SSD) according to an example of the present disclosure.

FIG. 18B is a schematic composition block diagram of an example memory according to an example of the present disclosure.

In the drawings, which are not necessarily drawn to scale, like reference numbers may describe similar components in different views. Like reference numbers having different letter suffixes may represent different examples of similar components. The drawings illustrate generally, by way of example, but not limitation, various examples discussed in the present document.

### DETAILED DESCRIPTION

As the feature size of semiconductor devices approaches the lower process limit, planar processes and manufacturing techniques become challenging and costly, and it is difficult to continue to increase the density of memory cells in semiconductor devices, bringing severe challenges to the semiconductor memory industry.

The technical solutions of the present disclosure will be further described in detail below with reference to the accompanying drawings and examples. Although example implementations of the present disclosure are shown in the drawings, it should be understood that the present disclosure may be implemented in various forms and should not be limited by the implementations set forth herein. On the contrary, these implementations are provided to enable a more thorough understanding of the present disclosure and to fully convey the scope of the present disclosure to those skilled in the art.

The present disclosure is described in more detail in the following paragraphs by way of example with reference to the accompanying drawings. The advantages and features of the present disclosure will be clearer according to the following description. It should be noted that the accompanying drawings are all in a very simplified form and are all in non-precise proportions, and are only used to conveniently and clearly assist in describing the examples of the present disclosure.

It should be understood that spatial relationship terms such as “under”, “below”, “lower”, “beneath”, “above”, “upper” and the like may be used herein for convenience of description to describe the relationship between one element or feature and other elements or features shown in the drawings. It will be understood that the spatially relative terms may encompass different orientations of the device in use or operation in addition to the orientation depicted in the figures. For example, if the device in the figures is turned over, an element described as “below” or “beneath” other elements or features would then be oriented “above” the other elements or features. Thus, the example terms “below” and “under” can encompass both upper and lower orientations. The device may be otherwise oriented (rotated 90 degrees or at other orientations) and the spatially relative descriptors used herein may be interpreted accordingly.

The terminology used herein is for the purpose of describing particular examples only and is not intended to be limiting of the disclosure. As used herein, the singular forms “a”, “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups. When used herein, the term “and/or” includes any and all combinations of the associated listed items.

In order to understand the features and technical contents of the examples of the present disclosure in more detail, the implementations of the examples of the present disclosure are described in detail below with reference to the accompanying drawings, and the accompanying drawings are for reference only and are not intended to limit the examples of the present disclosure.

It should be noted that the technical solutions described in the examples of the present disclosure may be arbitrarily combined without conflict.

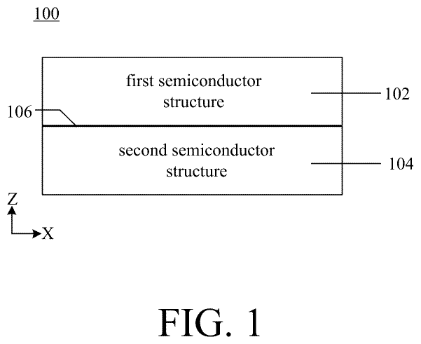

To further increase storage density, three-dimensional (3D) semiconductor device architectures may address density limitations in some planar semiconductor devices. As shown in FIG. 1, the semiconductor device 100 includes a first semiconductor structure 102 and a second semiconductor structure 104, for example, the first semiconductor structure 102 includes a memory array, and the second semiconductor structure 104 includes a peripheral circuit.

In some examples, in the manufacturing process of the semiconductor device, the first semiconductor structure 102 and the second semiconductor structure 104 are bonded together to obtain the semiconductor device. The memory array of the first semiconductor structure 102 includes a plurality of memory cells. For example, each memory cell mainly includes one transistor and one capacitor structure controlled by the transistor, that is, a dynamic random access memory (DRAM) includes an architecture of one transistor (T) and one capacitor structure (C) (e.g., a capacitor) (1T1C); and a main principle of the architecture is to use the amount of charges stored in the capacitor structure to represent whether a binary bit is 1 or 0.

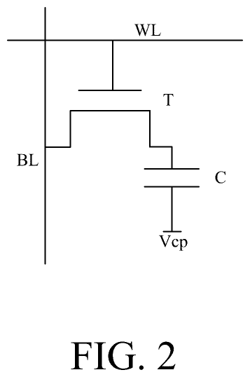

FIG. 2 is a schematic circuit connection diagram of a 1T1C architecture according to an example of the present disclosure. As shown in FIG. 2, the drain of the transistor T is electrically connected to a bit line (BL), the source of the transistor T is electrically connected to a first electrode of the capacitor structure C and a second electrode of the capacitor structure C is configured to receive a voltage Vcp, and a gate of the transistor T is connected to a word line (WL). The transistor T is controlled to be turned on or off by applying a voltage through the word line WL, and the bit line BL is configured to perform a read or write operation on the transistor T when the transistor T is turned on.

In some implementations, the memory cells in the first semiconductor structure include planar transistors, but since the sources and drains of the planar transistors are laterally disposed at different locations, which increases the transistor footprint, the design of the planar transistors also complicates the arrangement of word lines or bit lines coupled to the memory cells, e.g., limiting the spacing of the word lines or bit lines, thereby increasing manufacturing complexity and reducing product yield.

In some examples, to further reduce the overall size of the semiconductor device, the transistors of the memory cell are arranged as vertical transistors with vertical channel structures to reduce the planar size of the first semiconductor structure, thereby increasing the density of the semiconductor device.

In some implementations, when performing a read or write operation on the memory cell, a voltage Vcp needs to be applied to the second electrode of the capacitor structure. For example, when the transistor T is turned on by a word line voltage Vg, the capacitor structure C is charged or discharged in response to a bit line voltage Vbl. When the bit line voltage Vbl is at a logic high level (for example, Vcc), the capacitor structure C is charged, that is, stores “1”. Otherwise, capacitor structure C is discharged, e.g., stores “0”. Here, the second electrode of the capacitor structure C receives the voltage Vcp. For example, the voltage Vcp is 0 V or half of the power supply voltage (e.g., ½ Vcc). For example, in a write operation, the voltage Vcp may be adjusted to ½ Vcc to optimize the charging and discharging speed. In a read operation, the voltage Vcp may be adjusted to 0 V to improve sensing sensitivity. The specific value of the voltage Vcp depends on the design and operation requirements of the semiconductor device.

In the above examples, the voltage Vcp is configured to provide a stable reference voltage to ensure the stabilization of the charging and discharging processes of the capacitor structure, and the voltage Vcp affects the charging/discharging speed and efficiency of the capacitor structure. However, in a process of applying the voltage Vcp to the capacitor structure, wiring space of a conductive path of another structure (for example, a word line or a bit line) is occupied, so that the width of the wiring (for example, a conductive structure) on the conductive path of the another structure (for example, the word line or the bit line) is reduced and the resistance of the wiring is increased, causing a relatively large voltage drop (IR Drop), affecting a voltage received by the another structure in a read or write operation, thereby reducing overall performance of the semiconductor device. Therefore, improving a power delivery network (PDN) of a semiconductor device to improve performance of the semiconductor device becomes a technical problem that needs to be resolved urgently.

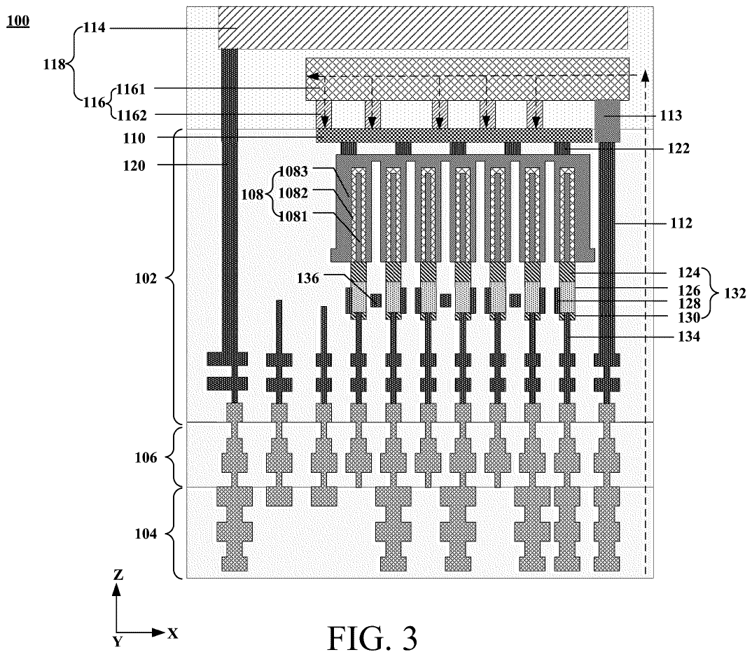

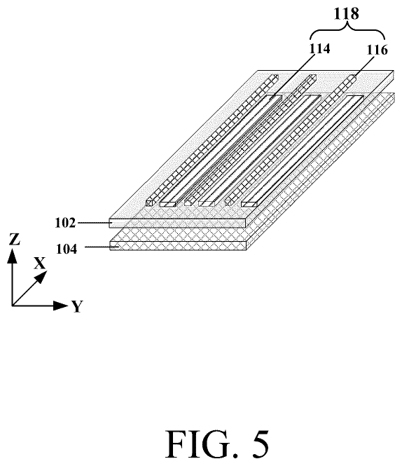

In view of this, examples of the present disclosure provide a semiconductor device, as shown in FIG. 3 and FIG. 5. The semiconductor device 100 includes: a first semiconductor structure 102 including a plurality of capacitor structures 108, at least one first electrode plate 110 and a first contact structure 112, the first electrode plate 110 being coupled to the plurality of capacitor structures 108; a second semiconductor structure 104 bonded to the first semiconductor structure 102; and a conductive structure 118 extending along a first direction and arranged at intervals along a second direction, where the conductive structure 118 is located on a side of the first semiconductor structure 102 away from the second semiconductor structure 104; the conductive structure 118 includes a plurality of first conductive structures 114 at least coupled to the second semiconductor structure 104, and second conductive structures 116 located between adjacent first conductive structures 114 and coupled to the first electrode plate 110; the first electrode plate 110 is located between the second conductive structures 116 and the plurality of capacitor structures 108; the first contact structure 112 extends along a third direction and located on a side of the first electrode plate 110 along the first direction, and a first end and a second end of the first contact structure 112 opposite to each other along the third direction are respectively coupled with the second conductive structure 116 and the second semiconductor structure 104.

Both the first direction and the second direction are parallel to a surface of the first electrode plate, the third direction is perpendicular to the surface of the first electrode plate, and the first direction intersects the second direction.

It should be noted that here and below, the first direction may be a direction in which the conductive structures extend, the second direction may be a direction in which the conductive structures are arranged at intervals, and the third direction may be a direction in which the first contact structure extends. The first direction and the second direction are both perpendicular to the third direction, and the first direction and the second direction intersect with each other. In some examples, the first direction is perpendicular to the second direction. For example, the first direction may be the X-axis direction shown in the drawings, the second direction may be the Y-axis direction shown in the drawings, and the third direction may be the Z-axis direction shown in the drawings.

Examples of the present disclosure set the conductive structure into first conductive structures and the second conductive structure that are alternately arranged along a second direction, on the one hand, electric field interference can be effectively reduced, and on the other hand, a conductive path formed by the first contact structure, a second conductive structure and the first electrode plate is provided for a capacitor structure, and the first conductive structures coupled to the second semiconductor structure are provided for a structure in the semiconductor device other than the capacitor structures, so as to improve the wiring density, reduce the overall resistance of the conductive structure, optimize the power delivery network of the semiconductor device, and realize efficient voltage delivery for the capacitor structures and other structures, thereby being beneficial for improving the integration level and performance of the semiconductor device.

In some examples, a capacitor structure 108 includes a first electrode 1081, a dielectric layer 1082 and a second electrode 1083; the dielectric layer 1082 covers a surface of the first electrode 1081, and the second electrode 1083 covers a surface of the dielectric layer 1082.

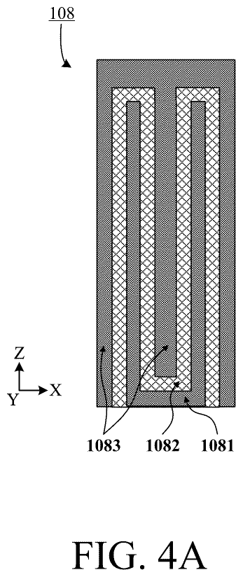

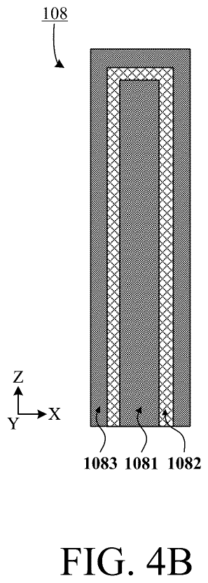

In some examples, the capacitor structure 108 may be a cylinder type shown in FIG. 4A or a pillar type shown in FIG. 4B. The type of the capacitor structure is not particularly limited by the semiconductor device according to the examples of the present disclosure.

In some examples, the material of the dielectric layer 1082 includes, but is not limited to, high-K materials such as hafnium oxide (HfO₂), aluminum oxide (Al₂O₃), hafnium aluminum oxide (HfAlO), hafnium lanthanum oxide (HfLaO), and zirconium oxide (ZrO₂). Materials of the first electrode 1081 and the second electrode 1083 include, but are not limited to, metal tungsten (W), metal cobalt (Co), metal nickel (Ni), or other conductive materials.

In some examples, as shown in FIG. 3, when a read or write operation is performed on a memory cell, the second semiconductor structure provides a voltage Vcp through the dotted line path to a capacitor structure 108 shown in FIG. 3. For example, the second semiconductor structure 104 applies the voltage Vcp to the second electrode 1083 of the capacitor structure 108 through the first contact structure 112, the first contact 113, the second conductive structure 116, and the second contact 122.

In some examples, the material of the first contact 113 and the second contact 122 include, but are not limited to, metal tungsten (W), metal cobalt (Co), metal copper (Cu), metal aluminum (Al), or other conductive materials. The arrangement of the first contact 113 is beneficial for realizing more uniform voltage transmission.

It should be noted that, in FIG. 3, in order to present the positional relationship among the first conductive structure and the second conductive structure, the first electrode plate and the capacitor structure, surfaces of the first conductive structures 114 and the second conductive structure 116 away from the second semiconductor structure are staggered along the third direction. In an actual semiconductor device, as shown in FIG. 5, surfaces of the first conductive structure 114 and the second conductive structure 116 away from the second semiconductor structure are flush along the third direction. In addition, FIG. 5 is a three-dimensional schematic diagram corresponding to FIG. 3, but for brevity, only the first semiconductor structure 102, the second semiconductor structure 104, and the conductive structure 118 are shown in FIG. 5, and other structures in FIG. 3 are omitted.

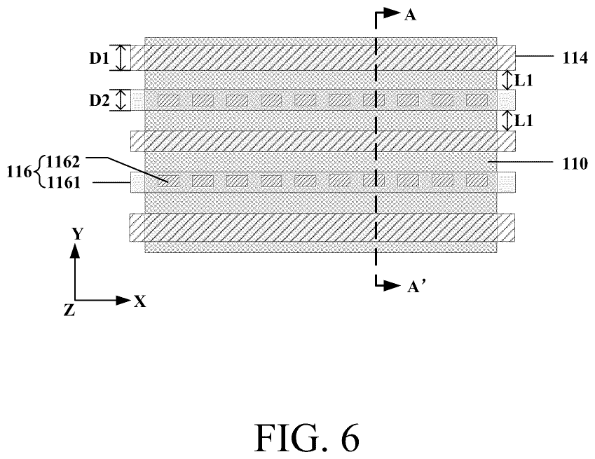

In some examples, along the second direction, a sum of sizes of the plurality of first conductive structures is greater than or equal to a sum of sizes of all of the second conductive structure. For example, as shown in FIG. 6, D1 is a size of a first conductive structure 114 along the second direction, D2 is a size of a second conductive structure 116 along the second direction, and a sum of sizes of three first conductive structures 114 shown in FIG. 6 is greater than or equal to a sum of sizes of two second conductive structures 116.

In some examples, because the first conductive structure is configured to provide a conductive path for the capacitor structure, the second conductive structure is configured to provide a conductive path for a structure (for example, a word line or a bit line 134 shown in FIG. 3) other than the capacitor structures in the semiconductor device. A voltage transmitted to a capacitor structure through a second conductive structure is usually less than or equal to a voltage transmitted to another structure (for example, a word line or a bit line) through a first conductive structure, so that according to a magnitude of an actually transmitted voltage, a sum of sizes of the plurality of first conductive structures along the second direction is set to be greater than or equal to a sum of sizes of all of the second conductive structure along the second direction, so that the resistance of the first conductive structure can be reduced without increasing an overall resistance of the conductive structure, and transmission requirements for voltages of different magnitudes in different structures in the semiconductor device can be met, thereby improving performance of the semiconductor device.

In some examples, along the second direction, a ratio of a sum of sizes of the plurality of first conductive structures 114 to a sum of sizes of all of the second conductive structure 116 ranges from 1 to 2. For example, the ratio of the sum of the sizes D1 of the plurality of first conductive structures 114 to the sum of the sizes D2 of all of the second conductive structure 116 is 1, 1.5, or 2.

In some examples, the size D1 of a first conductive structure 114 is equal to the size D2 of a second conductive structure 116.

For example, the size D1 of a first conductive structure 114 and the size D2 of a second conductive structure 116 shown in FIG. 6 both range from 5 micrometers (μm) to 10 μm.

In some examples, the spacings between the second conductive structure 116 and the two first conductive structures 114 adjacent to the second conductive structure 116 are equal.

For example, as shown in FIG. 6, the spacings between the second conductive structure 116 and the two first conductive structures 114 adjacent to the second conductive structure 116 both are L1. For example, L1 ranges from 5 μm to 10 μm. It should be noted that FIG. 6 illustrates that in the coverage of one first electrode plate 110, the sum of the sizes of the plurality of first conductive structures 114 is greater than or equal to the sum of the sizes of all of the second conductive structure 116 along the second direction.

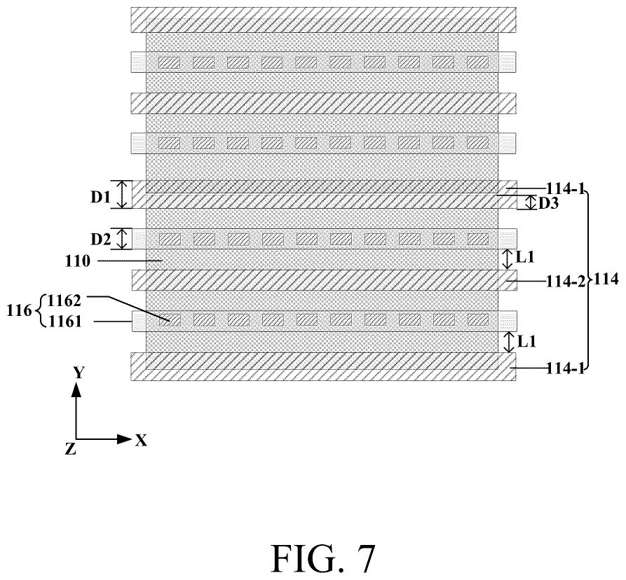

In other examples, as shown in FIG. 7, there may be a plurality of first electrode plates 110 (for example, two first electrode plates 110), and there is at least one first conductive structure 114 (for example, the first conductive structure 114-1) whose orthographic projection may simultaneously intersect the orthographic projections of two first electrode plates 110. As shown in FIG. 7, along the second direction, within the coverage of each first electrode plate 110, the effective size of the first conductive structure 114-1 is D3, and the effective size of the first conductive structure 114-2 is D1. In the example of FIG. 7, the sum of the sizes of the plurality of first conductive structures being greater than or equal to the sum of the sizes of all of the second conductive structure may be construed as the sum of the effective sizes of the plurality of first conductive structures being greater than or equal to the sum of the sizes of all of the second conductive structure. In other words, the sum of twice D3 and D1 is greater than twice D2.

In this way, when there are a plurality of first electrode plates, sizes of the first conductive structures and the second conductive structure disposed on each first electrode plate along the second direction meet the condition that a sum of sizes of the plurality of first conductive structures is greater than or equal to a sum of sizes of all of the second conductive structure, thereby meeting transmission requirements of structures in different regions in the semiconductor device for voltages of different magnitudes, and improving overall performance of the semiconductor device.

In some examples, the size D1 of a first conductive structure 114, the size D2 of a second conductive structure 116, and the spacing L1 are equal.

In some examples, as shown in FIG. 6, along the second direction, adjacent first conductive structures 114 are symmetrically distributed with respect to the second conductive structure 116 located between the adjacent first conductive structures 114. In this way, a wiring path conflict between a first conductive structure and a second conductive structure can be reduced, electric field interference can be reduced, an arrangement density of the first conductive structures and the second conductive structure can be increased, and integration level of the semiconductor device can be improved.

In some examples, the number of the first conductive structures 114 is greater than the number of the second conductive structure 116.

In some examples, a ratio of the number of the first conductive structures 114 to the number of the second conductive structure 116 ranges from 1.25 to 2. For example, the ratio of the number of the first conductive structures 114 and the number of the second conductive structure 116 may be 1.25, 1.5, or 2.

In some examples, the number of the first conductive structures is 5, and the number of the second conductive structure is 4.

In some examples, as shown in FIG. 6, the number of the first conductive structures is 3, and the number of the second conductive structure is 2.

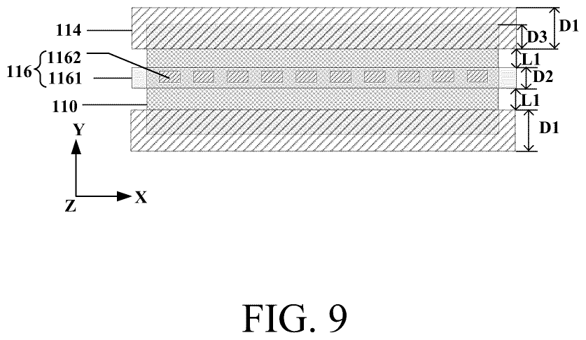

In some examples, as shown in FIG. 9, the number of the first conductive structures is 2, and the number of the second conductive structure is 1. For example, along the second direction, the size of the first conductive structure 114 is D1 and within the coverage of the first electrode plate 110, the effective size of the first conductive structure 114 is D3, and the effective size of the second conductive structure 116 is D2. In the example of FIG. 9, the sum of the sizes of the plurality of first conductive structures being greater than or equal to the sum of the sizes of all of the second conductive structure may be construed as the sum of the effective sizes of the plurality of first conductive structures being greater than or equal to the sum of the effective sizes of all of the second conductive structure, in other words, twice D3 is greater than or equal to D2.

In the example of FIG. 9, D1 is greater than D2. For example, D1 is equal to twice D2. For example, the size D1 of the first conductive structure 114 shown in FIG. 9 ranges from 10 μm to 20 μm.

The size D2 of the second conductive structure 116 ranges from 5 μm to 10 μm.

In some examples, there may be one (referring to FIG. 6) or more (referring to FIG. 7) first electrode plates 110.

It should be noted that the specific numbers of the first conductive structures, the second conductive structure, and the first electrode plates in the above examples are merely example descriptions, and are not intended to limit the numbers of the first conductive structures, the second conductive structure in the present disclosure. The numbers of first electrode plates, the first conductive structures, and the second conductive structure may be set according to actual requirements in practical applications.

In some examples, as shown in FIGS. 3, 6, 7 and 8, a second conductive structure 116 includes a plurality of conductive pillars 1162 arranged at intervals along the first direction, and a first conductive layer 1161 located on the plurality of conductive pillars 1162 and extending along the first direction; where the plurality of conductive pillars 1162 are located between the first electrode plate 110 and the first conductive layer 1161.

In some examples, the materials of the first conductive layer 1161 and the conductive pillars 1162 may be the same or different, for example, the materials of the first conductive layer 1161 and the conductive pillars 1162 include, but are not limited to, metal tungsten (W), metal cobalt (Co), metal copper (Cu), metal aluminum (Al), or other conductive materials.

It should be noted that, in FIG. 6, FIG. 7, and FIG. 9, to clearly show a positional relationship among the first conductive layer 1161, the conductive pillars 1162, and the first conductive structure 114, the first conductive layer 1161 is shown in a perspective manner.

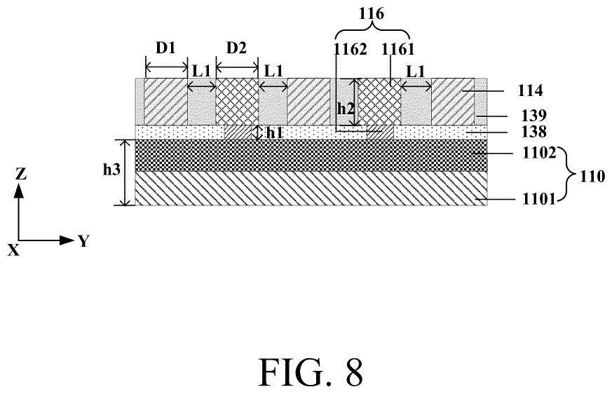

In some examples, as shown in FIG. 8, along the third direction, the ratio of the size h2 of the first conductive layer 1161 to the size h1 of the conductive pillar 1162 ranges from 7 to 8; and along the third direction, the ratio of the size h2 of the first conductive layer 1161 to the size h3 of the first electrode plate 110 ranges from 30 to 45.

For example, the ratio of the size h2 of the first conductive layer 1161 to the size h1 of the conductive pillar 1162 may be 7, 7.5, or 8, and the ratio of the size h2 of the first conductive layer 1161 to the size h3 of the first electrode plate 110 may be 30, 40 or 45.

In some examples, as shown in FIG. 8, the first electrode plate 110 includes a first sub-layer 1101 and a second sub-layer 1102, where the material of the first sub-layer 1101 includes, but is not limited to, silicon germanium, and the material of the second sub-layer 1102 includes, but is not limited to, metal tungsten (W) or tungsten nitride (WN).

In the examples of the present disclosure, by arranging the second conductive structure as the plurality of conductive pillars arranged at intervals along the first direction and the first conductive layer located on the plurality of conductive pillars and extending along the first direction, uniform voltage distribution can be achieved when transmitting a voltage to the first electrode plate through the second conductive structure, thereby reducing the fluctuation between the voltages received by the capacitor structures of the plurality of memory cells, and improving the performance of the semiconductor device.

In some examples, as shown in FIG. 3, the first semiconductor structure 102 further includes: a second contact structure 120 extending along the third direction, where the second contact structure 120 is located on a side of the first electrode plate 110 along the first direction, and a first end and a second end of the second contact structure 120 opposite to each other along the third direction are respectively coupled with a first conductive structure 114 and the second semiconductor structure 104.

In some examples, as shown in FIG. 3, the second contact structure 120 and the first contact structure 112 are located on different sides of the first electrode plate along the first direction. In this way, mutual interference between the first conductive structure and the second conductive structure during voltage transmission can be reduced.

In other examples, the second contact structure 120 and the first contact structure 112 may also be located on the same side of the first electrode plate along the first direction. In this way, wiring design can be simplified, occupied wiring space can be reduced, and wiring efficiency can be improved, thereby optimizing integration level of the semiconductor device.

In some examples, as shown in FIGS. 1 and 3, the second semiconductor structure 104 includes a peripheral circuit; the semiconductor device further includes: a bonding interface 106 located between the first semiconductor structure 102 and the second semiconductor structure 104; where the first conductive structure 114 is coupled to the peripheral circuit through at least the second contact structure 120 and the bonding interface 106; and the second conductive structure 116 is coupled to the peripheral circuit through the first contact structure 112 and the bonding interface 106.

In some examples, the first semiconductor structure further includes a vertical transistor 132, and the vertical transistor 132 includes: a vertical channel structure 126; a gate structure 128 located on at least one side of the vertical channel structure 126; a source 124 and a drain 130, where the source 124 and the drain 130 are respectively located on two opposite sides of the vertical channel structure 126 along the third direction; a first electrode 1081 of a capacitor structure 108 is connected with one of the source 124 or the drain 130; and the second electrodes 1083 of the plurality of capacitor structures 108 are coupled with the first electrode plate 110.

In some examples, as shown in FIG. 3, the first semiconductor structure 102 further includes a shielding layer 136. The shielding layer 136 is located on a side of the vertical channel structures 126 of two adjacent vertical transistors 132 where non gate structure 128 is disposed.

In some examples, the material of the vertical channel structure 126 includes at least one of indium gallium zinc oxide (IGZO), indium tungsten oxide (IWO), indium tin oxide (ITO), and indium-zinc oxide (IZO). When the material of the vertical channel structure 126 is IGZO, the leakage current of the vertical transistor is small (less than or equal to 10⁻¹⁵ A), thereby ensuring a low refresh rate of the dynamic random access memory. For example, the material of the shielding layer 136 includes, but is not limited to, metal tungsten (W), metal cobalt (Co), metal copper (Cu), metal aluminum (Al), or another conductive material. In some examples, the material of the shielding layer 136 is metal tungsten.

As the density of semiconductor devices continues to increase, gate structures of memory cells of the semiconductor devices become physically closer such that capacitive coupling between adjacent memory cells increases. By providing the shielding layer between the vertical transistors of the adjacent memory cells, the coupling capacitance between the adjacent memory cells can be effectively reduced, and the row hammer effect can be alleviated.

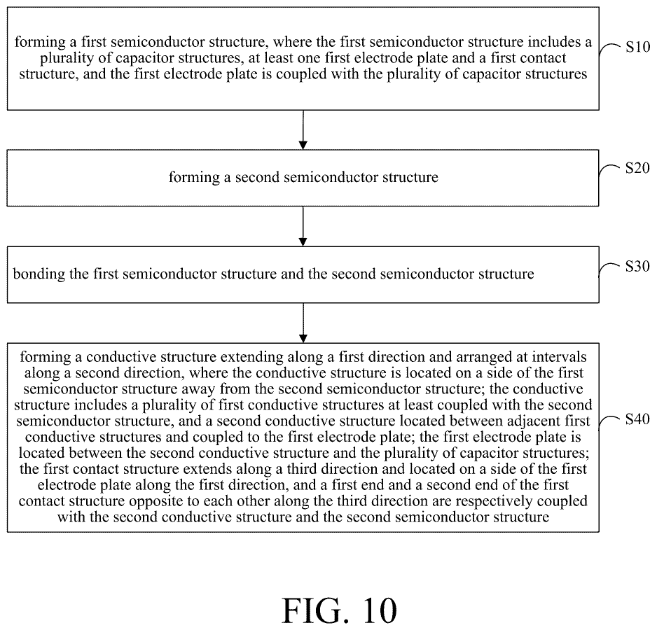

An example of the present disclosure further provides a method for forming a semiconductor device. FIG. 10 is a flowchart of a method for forming a semiconductor device according to an example of the present disclosure. As shown in FIG. 10, the method for forming a semiconductor device includes following operations:
Operation S10: forming a first semiconductor structure, where the first semiconductor structure includes a plurality of capacitor structures, at least one first electrode plate and a first contact structure, and the first electrode plate is coupled with the plurality of capacitor structures;
Operation S20: forming a second semiconductor structure;
Operation S30: bonding the first semiconductor structure and the second semiconductor structure;
Operation S40: forming a conductive structure extending along the first direction and arranged at intervals along a second direction, where the conductive structure is located on a side of the first semiconductor structure away from the second semiconductor structure; the conductive structure includes a plurality of first conductive structures at least coupled with the second semiconductor structure, and a second conductive structure located between adjacent first conductive structures and coupled to the first electrode plate; the first electrode plate is located between the second conductive structure and the plurality of capacitor structures; the first contact structure extends along a third direction and located on a side of the first electrode plate along the first direction, and a first end and a second end of the first contact structure opposite to each other along the third direction are respectively coupled with the second conductive structure and the second semiconductor structure.

Both the first direction and the second direction are parallel to a surface of the first electrode plate, the third direction is perpendicular to the surface of the first electrode plate, and the first direction intersects the second direction.

It should be understood that the operations shown in FIG. 10 are not exclusive, and other operations may be performed before, after, or between any of the operations shown; the order of operations shown in FIG. 10 may be adjusted according to actual requirements.

In some examples, along the second direction, the sum of the sizes of the plurality of first conductive structures along the second direction is greater than or equal to a sum of sizes of all of the second conductive structure along the second direction.

A voltage transmitted to a capacitor structure through a second conductive structure is usually less than or equal to a voltage transmitted to another structure (for example, a word line or a bit line) through a first conductive structure, so that according to a magnitude of an actually transmitted voltage, a sum of sizes of the plurality of first conductive structures along the second direction is set to be greater than or equal to a sum of sizes of all of the second conductive structure along the second direction, so that the resistance of the first conductive structure can be reduced without increasing an overall resistance of the conductive structure, and transmission requirements for voltages of different magnitudes in different structures in the semiconductor device can be met, thereby improving performance of the semiconductor device.

Next, a process of forming a semiconductor device will be described in detail with reference to FIGS. 3, 6, 8 and 16.

Operation S10 is performed to form a first semiconductor structure 102.

In some examples, as shown in FIG. 3, forming the first semiconductor structure 102 further includes: forming a vertical channel structure 126; forming a gate structure 128 on at least one side of the vertical channel structure 126; forming a source 124 and a drain 130, where the source 124 and the drain 130 are respectively located on two opposite sides of the vertical channel structure 126 in the thickness direction of the first electrode plate 110, and the vertical channel structure 126, the gate structure 128, the source 124, and the drain 130 constitute a vertical transistor 132; and forming a capacitor structure 108, where the capacitor structure 108 is connected with one of the source 124 or the drain 130.

Referring to FIG. 3, the capacitor structure 108 includes a first electrode 1081, a dielectric layer 1082 and a second electrode 1083; the dielectric layer 1082 covers a surface of the first electrode 1081, and the second electrode 1083 covers a surface of the dielectric layer 1082. The first electrode 1081 of the capacitor structure 108 is connected with the source 124, the second electrodes 1083 of the plurality of capacitor structures 108 are coupled with the first electrode plate 110, and the bit line 134 is coupled to the drain 130.

In some examples, the extending direction of the word lines is perpendicular to the extending direction of the bit lines. In some examples, the gate structure surrounds two sides of the vertical channel structure (one side of the vertical channel structure along the first direction and one side of the vertical channel structure along the second direction), a word line (not shown in FIG. 3) extends along the first direction and is connected with the gate structures of a plurality of vertical transistors arranged along the first direction, and a bit line extends along the second direction and is connected with the drains of a plurality of vertical transistors arranged along the second direction.

Operation S20 is performed to form a second semiconductor structure 104.

Operation S30 is performed to bond the first semiconductor structure 102 and the second semiconductor structure 104. The first semiconductor structure 102 and the second semiconductor structure 104 are connected through a bonding interface 106; and the first semiconductor structure 102 and the second semiconductor structure 104 may be connected through hybrid bonding or the like. In some examples, the first semiconductor structure 102 may be bonded on top of the second semiconductor structure 104 in a face-to-face manner at the bonding interface 106.

Operation S40 is performed to form a conductive structure 118 extending along the first direction and arranged at intervals along the second direction.

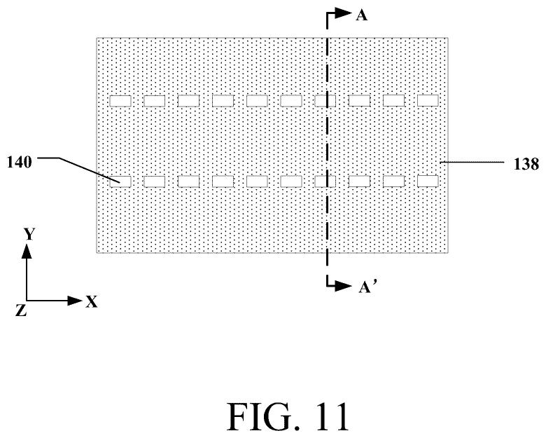

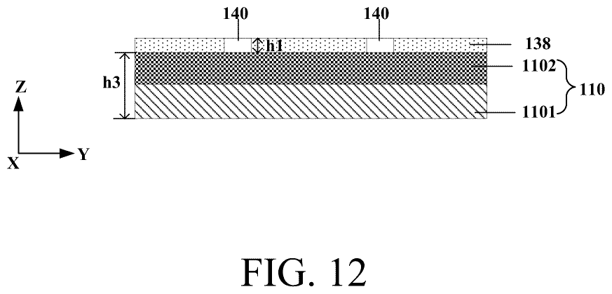

As shown in FIG. 11 and FIG. 12, a plurality of through holes 140 exposing a part of the first electrode plate 110 are formed on a side of the first semiconductor structure away from the second semiconductor structure, and the plurality of through holes 140 are arranged at intervals along the first direction. For example, a first dielectric layer 138 covering the first electrode plate 110 is formed on a side of the first semiconductor structure away from the second semiconductor structure, and a part of the first dielectric layer 138 is removed to form a plurality of through holes 140 exposing a part of the first electrode plate 110.

In some implementations, the method of forming the first dielectric layer 138 includes, but is not limited to, processes such as physical vapor deposition (PVD), chemical vapor deposition (CVD), and atomic layer deposition (ALD).

In some implementations, the method of forming the through holes 140 includes, but is not limited to, dry etching or wet etching.

In some implementations, the size of the through holes 140 along the third direction is equal to h1.

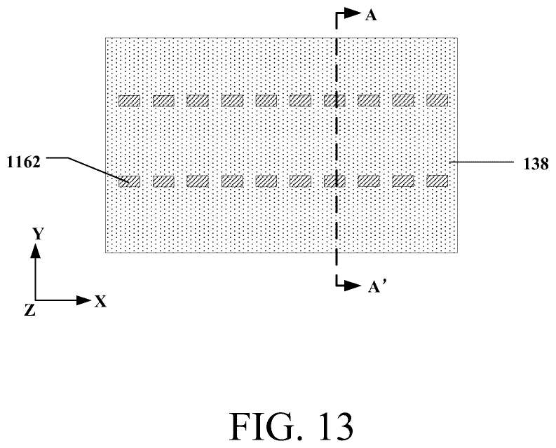

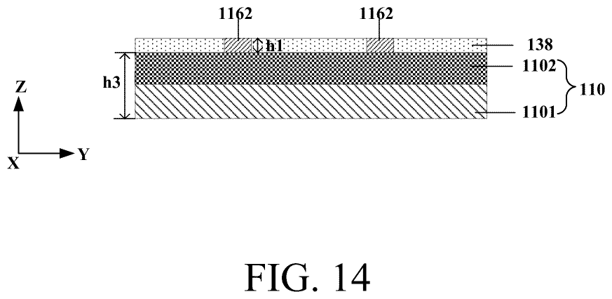

As shown in FIG. 13 and FIG. 14, the plurality of through holes are filled with a first conductive material to form a plurality of conductive pillars 1162. For example, the first conductive material includes, but is not limited to, metal tungsten (W), metal cobalt (Co), metal copper (Cu), or metal aluminum (Al).

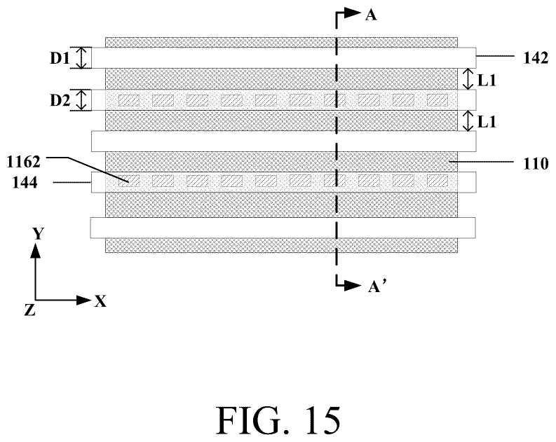

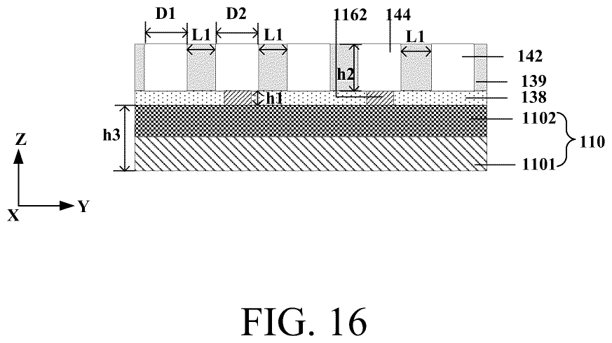

As shown in FIG. 15 and FIG. 16, a plurality of first trenches 142 arranged at intervals along the second direction and second trench 144 located between adjacent first trenches 142 are formed on a side of the first semiconductor structure away from the second semiconductor structure; the first trenches 142 and the second trench 144 both extend along the first direction, and the second trench 144 expose a surface of the conductive pillars 1162.

For example, a second dielectric layer 139 covering the plurality of conductive pillars 1162 is formed on a side of the first semiconductor structure away from the second semiconductor structure, and a part of the second dielectric layer 139 is removed to form a plurality of first trenches 142 and to form second trench 144 exposing a surface of the conductive pillars 1162.

In some examples, the spacings between a second trench 144 and the two first trenches 142 adjacent to the second trench 144 are equal.

For example, as shown in FIG. 15 and FIG. 16, spacings between a second trench 144 and the two first trenches 142 adjacent to the second trench 144 are both L1.

It should be noted that, in order to present the positional relationship between the first trenches, the second trench, and the conductive pillars, structures such as the first dielectric layer and the second dielectric layer are omitted in FIG. 15.

In some examples, along the second direction, the sum of the sizes of the plurality of first trenches 142 is greater than or equal to the sum of sizes of all of the second trench 144. For example, along the second direction, the size of a first trench 142 along the second direction is equal to D1, and the size of a second trench 144 along the second direction is equal to D2. As shown in FIG. 15 and FIG. 16, the sum of the sizes of the three first trenches 142 along the second direction is greater than or equal to the sum of the sizes of the two second trenches 144 along the second direction.

In some examples, along the second direction, the ratio of the sum of the sizes of the plurality of first trenches 142 to the sum of the sizes of all of the second trench 144 ranges from 1 to 2. For example, the ratio of the sum of the sizes of the plurality of first conductive structures 114 to the sum of the sizes of all of the second conductive structure 116 is 1, 1.5 or 2.

In some examples, along the third direction, the ratio of the size of a second trench along the third direction to the size of a through hole ranges from 7 to 8; and along the third direction, the ratio of the size of a second trench to the size of the first electrode plate ranges from 30 to 45. For example, along the third direction, the size of a second trench 144 is equal to h2, the size of the first electrode plate is equal to h3, the ratio of h2 to h1 ranges from 7 to 8, and the ratio of h2 to h3 ranges from 30 to 45. For example, the ratio of h2 to h1 is 7, 7.5 or 8, and the ratio of h2 to h3 is 30, 40 or 45.

As shown in FIGS. 6 and 8, the plurality of first trenches 142 and the second trench 144 are filled with a second conductive material to form second conductive layers of the first conductive structures 114 and first conductive layers 1161 of the second conductive structure 116, respectively.

In some implementations, the second conductive material may be the same as the first conductive material.

An example of the present disclosure further provides a memory system, including: at least one of any of the semiconductor devices of the first aspect; and a controller configured to control the semiconductor device.

Here, the semiconductor device may be a memory or a part of the memory.

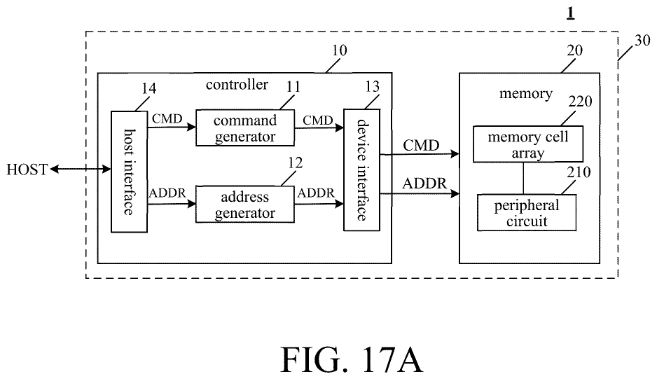

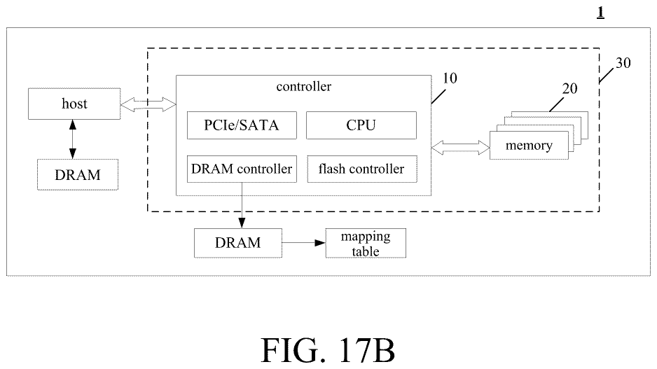

FIG. 17A shows a schematic composition block diagram of an example system according to an example of the present disclosure. As shown in FIG. 17A, the system 1 may include a host HOST and a memory system 30 including a controller 10 and one or more memories 20. The host HOST may be a processor (e.g., a central processing unit (CPU) or a graphic processing unit (GPU)) of an electronic device. The host HOST may be configured to send data to or receive data from the memory 20. The controller 10 is coupled to the memory 20 and the host HOST, and is configured to control the memory 20. The controller 10 may manage data stored in the memory 20, and communicate with the HOST.

The controller 10 may be configured to control operations of the memory 20, such as read, write, and refresh operations. In some implementations, the controller 10 is further configured to process an error correction code (ECC) on data read from or written to the memory 20. The controller 10 may also perform any other suitable functions, such as formatting the memory 20.

In some examples, the controller 10 and the one or more memories 20 may all be integrated into various types of electronic devices, for example, the controller 10 may be integrated into a north bridge of a computer motherboard or directly into a computer CPU, and the plurality of memories 20 may be integrated into a memory module. That is, the memory system 30 may be implemented and packaged into different types of end electronic products.

The controller 10 may send/receive data to/from the HOST, and may send a command CMD and an address ADDR to the memory 20. The controller 10 may include a command generator 11, an address generator 12, a device interface 13, and a host interface 14. The host interface 14 may receive a command CMD and an address ADDR from the HOST, the command generator 11 may generate an access command, a row hammer refresh command, or the like by decoding the command CMD received from the host HOST, and may provide the access command and the row hammer refresh command to the memory 20 through the device interface 13. The access command may be a signal instructing the memory 20 to write or read data by accessing a row of the memory cell array 220 corresponding to the address ADDR. The row hammer refresh command may be a signal that commands the memory 20 to perform additional refresh operations on a word line adjacent to a word line that is densely accessed for a short period of time. In other words, additional refresh operations may be performed on a word line adjacent to a word line that is accessed multiple times in a short period of time.

The address generator 12 in the controller 10 may generate a row address and a column address to be accessed in the memory cell array 220 by decoding the address ADDR received from the host interface 14. In addition, the memory 20 may generate an address of a memory bank to be accessed when the memory cell array 220 includes a plurality of memory banks.

Further, the controller 10 may control memory operations such as writing and reading by providing various signals to the memory 20 via the device interface 13. For example, the controller 10 may provide a write command to the memory 20. The write command is configured to instruct the memory 20 to perform a write operation to store data into the memory 20.

In some examples, the memory 20 includes a memory cell array 220 and a peripheral circuit 210, where the memory cell array 220 includes a plurality of memory banks, each memory bank includes a plurality of memory blocks, each memory block includes a plurality of memory cell rows and a plurality of memory cell columns, each memory cell row is coupled with a corresponding word line, and each memory cell column is coupled with a corresponding bit line. The peripheral circuit 210 may write data to the memory cell array 220 or read data from the memory cell array 220 based on a command CMD and an address ADDR received from the controller 10, or may provide control signals CTRL for refreshing memory cells included in the memory cell array 220 to a row decoding circuit and a column decoding circuit. In other words, the peripheral circuit 210 may perform all operations to process data in the memory cell array 220. The peripheral circuit 210 may include a control circuit corresponding to each memory block, such as a sensing amplifier (SA) circuit and a word line driver (WLD) circuit, a control circuit corresponding to each memory bank, such as a row decoding circuit and a column decoding circuit, and a control circuit corresponding to all memory banks, such as a command buffer, a command decoder, an address buffer, a data input/output buffer, and a mode register.

The memory 20 may be random access memory (RAM) such as dynamic random access memory (DRAM), synchronous DRAM (SDRAM), static RAM (SRAM), double data rate SDRAM (DDR SDRAM), DDR2 SDRAM, DDR3 SDRAM, phase change RAM (PRAM), magnetic RAM (MRAM), resistive RAM (RRAM), etc. The following uses DRAM as an example for description.

FIG. 17B shows a schematic composition diagram of an example system according to an example of the present disclosure. In some examples, the DRAM may belong to a structure outside the memory system 30 which may be directly connected to the host to serve as a main memory of the host during runtime, or the DRAM may be embedded in the host. In some examples, the DRAM may belong to a structure outside the memory system 30 which may be coupled to the memory system 30 to be used as a cache memory, for example, for storing a mapping table. In some examples, the DRAM serving as a cache memory may also be embedded in the controller 10. In some other examples, the DRAM may also belong to a part of the controller 10, for example, the DRAM serving as a cache memory is embedded in the controller 10. In some examples, the DRAM may also belong to a part of the controller 10, for example, a part of the DRAM controller, for controlling the memory 20 to perform operations such as writing and reading. In some other examples, multiple-DRAM stack arrangement may be applied to a high bandwidth memory (HBM) architecture for use as a storage medium.

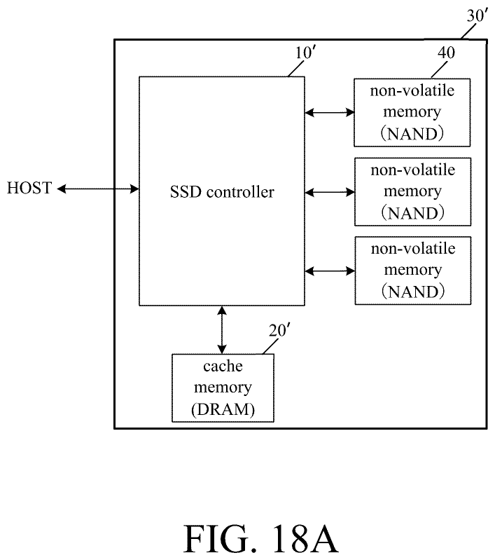

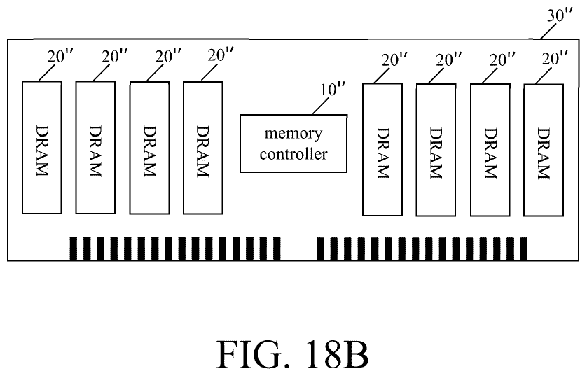

FIG. 18A is a composition block diagram of an example SSD according to an example of the present disclosure. Herein, the SSD may be construed as one of the memory systems in FIG. 17A and FIG. 17B, and in this example, the DRAM may be used as a cache memory.

As shown in FIG. 18A, SSD 30′ may include an SSD controller 10′, a cache memory 20′, and a non-volatile memory 40. The SSD controller 10′ may provide a physical connection between the HOST and the SSD 30′. That is, the SSD controller 10′ may provide an interface between the HOST and the SSD 30′ in the bus format of the host. The SSD controller 10′ may decode instructions provided from the HOST. The SSD controller 10′ may access the non-volatile memory 40 based on the decoding result. The cache memory 20′ may temporarily store write data provided from the HOST or data read from the non-volatile memory 40. When the HOST issues a read request, the cache memory 20′ may support a caching function for providing cached data directly to the HOST if the data present in the non-volatile memory 40 is cached. The data transfer rate through the bus format of the host (e.g., SATA (Serial Advanced Technology Attachment) or SAS (Serial Attached SCSI (Small Computer System Interface))) is much higher than the data transfer rate of the memory channels of the SSD 30′. That is, when the interface speed of the host is significantly high, performance degradation due to speed differences can be minimized by providing a high capacity cache memory 20′. In addition, the cache memory 20′ may store an address a mapping table of the non-volatile memory 40. The cache memory 20′ may include, but is not limited to, DRAM. The non-volatile memory 40 may be configured as a storage medium of the SSD 30′. The non-volatile memory 40 may include, but is not limited to, a NAND type memory.

FIG. 18B is a composition block diagram of an example memory according to an example of the present disclosure; here, the memory may be understood as one of the memory systems in FIG. 17A, and in this example, the DRAM may be used as a storage medium.

As shown in FIG. 18B, the memory 30″ can be easily attached or installed to or detached from the system 1 through the illustrated interface. The memory 30″ may include a plurality of volatile memories 20″ (e.g., DRAMs) and a memory controller 10″. The memory 30″ may be configured to write data, store data, retrieve (or read) data, and/or erase data under the controller of the processor of the computer. In some examples, the memory controller 10″ may communicate with the DRAM using at least one communication protocol or technical standard commonly associated with, for example, dual in-line memory modules (DIMMs), registered DIMMs (RDIMMs), low load DIMMs (LRDIMMs), unregistered DIMMs (UDIMMs), etc.

It should be noted that both the cache memory 20′ in FIG. 18A and the volatile memory 20″ in FIG. 18B are an application scenario of the memory 20 in FIG. 17A.

It should be understood that “an example” or “some examples” mentioned throughout the specification means that particular features, structures, or characteristics related to the example(s) are included in at least one example of the present disclosure. Therefore, “in an example” or “in some examples” appearing throughout the specification does not necessarily refer to same example(s). Furthermore, the particular features, structures, or characteristics may be combined in any suitable manner in one or more examples. It should be understood that, in various examples of the present disclosure, the sequence numbers of the above processes do not mean an execution sequence, and the execution sequence of each process should be determined by its function and internal logic, and the sequence numbers should not constitute any limitation on the implementation process of the examples of the present disclosure. The sequence numbers of the above examples of the present disclosure are only for description, and do not represent the advantages and disadvantages of the examples.

In view of this, examples of the present disclosure provide a semiconductor device, a method for forming the same, and a memory system.

According to a first aspect of the examples of the present disclosure, there is provided a semiconductor device, including: a first semiconductor structure, where the first semiconductor structure includes a plurality of capacitor structures, at least one first electrode plate and a first contact structure, where the first electrode plate is coupled with the plurality of capacitor structures; a second semiconductor structure bonded to the first semiconductor structure; and a conductive structure extending along a first direction and arranged at intervals along a second direction, where the conductive structure is located on a side of the first semiconductor structure away from the second semiconductor structure; the conductive structure includes a plurality of first conductive structures at least coupled with the second semiconductor structure and a second conductive structure located between adjacent first conductive structures and coupled to the first electrode plate; the first electrode plate is located between the second conductive structure and the plurality of capacitor structures; the first contact structure extends along a third direction and is located on a side of the first electrode plate along the first direction, and a first end and a second end of the first contact structure opposite to each other along the third direction are respectively coupled with the second conductive structure and the second semiconductor structure; where the first direction and the second direction are both parallel to a surface of the first electrode plate, the third direction is perpendicular to the surface of the first electrode plate, and the first direction intersects the second direction.

In an optional implementation, along the second direction, along the second direction, a sum of sizes of the plurality of first conductive structures is greater than or equal to a sum of sizes of all of the second conductive structure.

In an optional implementation, along the second direction, a ratio of a sum of sizes of the plurality of first conductive structures to a sum of sizes of all of the second conductive structure ranges from 1 to 2.

In an optional implementation, spacings between the second conductive structure and two first conductive structures adjacent to the second conductive structure are equal.

In an optional implementation, along the second direction, adjacent first conductive structures are symmetrically distributed with respect to the second conductive structure located between the adjacent first conductive structures.

In an optional implementation, a number of the first conductive structures is greater than a number of the second conductive structure.

In an optional implementation, a ratio of the number of the first conductive structures to the number of the second conductive structure ranges from 1.5 to 2.

In an optional implementation, a second conductive structure includes a plurality of conductive pillars arranged at intervals along the first direction and a first conductive layer located on the plurality of conductive pillars and extending along the first direction; and the plurality of conductive pillars are located between the first electrode plate and the first conductive layer.

In an optional implementation, along the third direction, a ratio of a size of the first conductive layer to a size of the conductive pillar ranges from 7 to 8; and along the third direction, a ratio of a size of the first conductive layer to a size of the first electrode plate ranges from 30 to 45.

In an optional implementation, the first semiconductor structure further includes a second contact structure extending along a third direction, where the second contact structure is located on a side of the first electrode plate along the first direction, and a first end and a second end of the second contact structure opposite to each other along the third direction are respectively coupled with a first conductive structure and the second semiconductor structure.

In an optional implementation, the second semiconductor structure includes a peripheral circuit; and the semiconductor device further includes: a bonding interface located between the first semiconductor structure and the second semiconductor structure; where the first conductive structure is coupled to the peripheral circuit through at least the second contact structure and the bonding interface; and the second conductive structure is coupled to the peripheral circuit through the first contact structure and the bonding interface.

In an optional implementation, a capacitor structure includes a first electrode, a dielectric layer and a second electrode; the dielectric layer covers a surface of the first electrode, and the second electrode covers a surface of the dielectric layer; and the first semiconductor structure further includes a vertical transistor, where the vertical transistor includes: a vertical channel structure; a gate structure located on at least one side of the vertical channel structure; a source and a drain respectively located on two opposite sides of the vertical channel structure along the third direction; the first electrode of the capacitor structure is connected with one of the source or the drain; and the second electrodes of the plurality of capacitor structures are coupled with the first electrode plate.

According to a second aspect of the examples of the present disclosure, there is provided a memory system, including: at least one of any of the semiconductor devices of the first aspect; and a controller configured to control the semiconductor device.

According to a third aspect of the examples of the present disclosure, there is provided a method for forming a semiconductor device, including: forming a first semiconductor structure, where the first semiconductor structure includes a plurality of capacitor structures, at least one first electrode plate and a first contact structure, and the first electrode plate is coupled with the plurality of capacitor structures; forming a second semiconductor structure; bonding the first semiconductor structure and the second semiconductor structure; and forming a conductive structure extending along a first direction and arranged at intervals along a second direction, where the conductive structure is located on a side of the first semiconductor structure away from the second semiconductor structure; the conductive structure includes a plurality of first conductive structures at least coupled with the second semiconductor structure and a second conductive structure located between adjacent first conductive structures and coupled to the first electrode plate; the first electrode plate is located between the second conductive structure and the plurality of capacitor structures; the first contact structure extends along a third direction and is located on a side of the first electrode plate along the first direction, and a first end and a second end of the first contact structure opposite to each other along the third direction are respectively coupled with the second conductive structure and the second semiconductor structure; and where the first direction and the second direction are both parallel to a surface of the first electrode plate, the third direction is perpendicular to the surface of the first electrode plate, and the first direction intersects the second direction.

In an optional implementation, along the second direction, a sum of sizes of the plurality of first conductive structures is greater than or equal to a sum of sizes of all of the second conductive structure.

In an optional implementation, forming the conductive structure extending along the first direction and arranged at intervals along the second direction includes: forming, on a side of the first semiconductor structure away from the second semiconductor structure, a plurality of through holes exposing a part of the first electrode plate, where the plurality of through holes are arranged at intervals along the first direction; filling the plurality of through holes with a first conductive material to form a plurality of conductive pillars; forming, on a side of the first semiconductor structure away from the second semiconductor structure, a plurality of first trenches arranged at intervals along the second direction and a second trench located between adjacent first trenches, where the first trenches and the second trench both extend along the first direction, and the second trench exposes a surface of the conductive pillar; and filling the plurality of first trenches and the second trench with a second conductive material to respectively form a second conductive layer of the first conductive structures and a first conductive layer of the second conductive structure.

In an optional implementation, along the second direction, a sum of sizes of the plurality of first trenches is greater than or equal to a sum of sizes of all of the second trench.

In an optional implementation, along the second direction, a ratio of a sum of sizes of the plurality of first trenches to a sum of sizes of all of the second trench ranges from 1 to 2.

In an optional implementation, along the third direction, a ratio of a size of the second trench to a size of the through hole ranges from 7 to 8; and along the third direction, a ratio of a size of the second trench to a size of the first electrode plate ranges from 30 to 45.

In an optional implementation, forming the first semiconductor structure further includes: forming a vertical channel structure; forming a gate structure on at least one side of the vertical channel structure; forming a source and a drain, where the source and the drain are respectively located on two opposite sides of the vertical channel structure along a thickness direction of the first electrode plate; and forming a capacitor structure, where the capacitor structure is connected with one of the source or the drain.

In the technical solutions according to the examples of the present disclosure, a semiconductor device is provided, a first semiconductor structure in the semiconductor device includes a plurality of capacitor structures and a first electrode plate, and coupling between a second semiconductor structure and a capacitor structure is realized through a first contact structure, the first electrode plate and a second conductive structure, and in addition, a first conductive structure coupled to the second semiconductor structure is provided for a structure other than the capacitor structures in the semiconductor device. Examples of the present disclosure set the conductive structure into first conductive structures and the second conductive structure that are alternately arranged along a second direction, on the one hand, electric field interference can be effectively reduced, and on the other hand, a conductive path formed by the first contact structure, a second conductive structure and the first electrode plate is provided for a capacitor structure, and the first conductive structures coupled to the second semiconductor structure are provided for a structure in the semiconductor device other than the capacitor structures, so as to improve the wiring density, reduce the overall resistance of the conductive structure, optimize the power delivery network of the semiconductor device, and realize efficient voltage delivery for the capacitor structures and other structures, thereby being beneficial for improving the integration level and performance of the semiconductor device.

The above is only detailed description of this disclosure, but the protection scope of this disclosure is not limited to this. Changes or replacements that any skilled person familiar with this technical field can easily think of within the technical scope disclosed in this disclosure should be included in the protection scope of this disclosure.

What is claimed is:

1. A semiconductor device, comprising:
a first semiconductor structure including a plurality of capacitor structures, a first electrode plate and a first contact structure, wherein the first electrode plate is coupled with the plurality of capacitor structures;
a second semiconductor structure bonded to the first semiconductor structure; and
a conductive structure extending along a first direction and arranged at intervals along a second direction, wherein the conductive structure is located on a side of the first semiconductor structure away from the second semiconductor structure, the conductive structure includes a plurality of first conductive structures coupled with the second semiconductor structure and a plurality of second conductive structures, the second conductive structures between adjacent ones of the first conductive structures and coupled to the first electrode plate, the first electrode plate is located between the second conductive structures and the plurality of capacitor structures, the first contact structure extends along a third direction and is located on a side of the first electrode plate along the first direction, and a first end and a second end of the first contact structure opposite to each other along the third direction coupled with corresponding ones of the second conductive structures and the second semiconductor structure, and wherein the first direction and the second direction are both parallel to a surface of the first electrode plate, the third direction is perpendicular to the surface of the first electrode plate, and the first direction intersects the second direction.

2. The semiconductor device of claim 1, wherein along the second direction, a sum of sizes of the plurality of first conductive structures is greater than or equal to a sum of sizes of all of the second conductive structures.

3. The semiconductor device of claim 2, wherein along the second direction, a ratio of the sum of sizes of the plurality of first conductive structures to a sum of sizes of all of the second conductive structures ranges from 1 to 2.

4. The semiconductor device of claim 2, wherein spacings between the second conductive structures and the first conductive structures adjacent to the second conductive structures are equal.

5. The semiconductor device of claim 2, wherein along the second direction, the first conductive structures are symmetrically distributed with respect to the second conductive structures located between the first conductive structures.

6. The semiconductor device of claim 1, wherein a number of the first conductive structures is greater than a number of the second conductive structures.

7. The semiconductor device of claim 6, wherein a ratio of the number of the first conductive structures to the number of the second conductive structures ranges from 1.5 to 2.

8. The semiconductor device of claim 1, wherein:
at least one of the second conductive structures includes a plurality of conductive pillars arranged at intervals along the first direction and a first conductive layer located on the plurality of conductive pillars and extending along the first direction; and
the plurality of conductive pillars are located between the first electrode plate and the first conductive layer.

9. The semiconductor device of claim 8, wherein
along the third direction, a ratio of a size of the first conductive layer to a size of a conductive pillar of the plurality of conductive pillars ranges from 7 to 8; and
along the third direction, a ratio of the size of the first conductive layer to a size of the first electrode plate ranges from 30 to 45.

10. The semiconductor device of claim 1, wherein the first semiconductor structure further includes:
a second contact structure extending along the third direction, wherein the second contact structure is located on the side of the first electrode plate along the first direction, and a first end and a second end of the second contact structure opposite to each other along the third direction are respectively coupled with at least one of the first conductive structures and the second semiconductor structure.

11. The semiconductor device of claim 10, wherein the second semiconductor structure includes a peripheral circuit, and the semiconductor device further includes:
a bonding interface between the first semiconductor structure and the second semiconductor structure, wherein:
the at least one of the first conductive structures is coupled to the peripheral circuit through at least the second contact structure and the bonding interface, and at least one of the second conductive structures is coupled to the peripheral circuit through the first contact structure and the bonding interface.

12. The semiconductor device of claim 1, wherein:
a first capacitor structure of the plurality of capacitor structures includes a first electrode, a dielectric layer and a second electrode;
the dielectric layer covers a surface of the first electrode, and the second electrode covers a surface of the dielectric layer; and
the first semiconductor structure further includes a vertical transistor, wherein the vertical transistor includes:
a vertical channel structure;
a gate structure located on at least one side of the vertical channel structure; and
a source and a drain respectively located on opposite sides of the vertical channel structure along the third direction, wherein:
the first electrode of the first capacitor structure is connected with one of the source or the drain, and the second electrode of the first capacitor structure is coupled with the first electrode plate.

13. A memory system, comprising:
at least one semiconductor device including:
a first semiconductor structure including a plurality of capacitor structures, a first electrode plate and a first contact structure, wherein the first electrode plate is coupled with the plurality of capacitor structures;
a second semiconductor structure bonded to the first semiconductor structure; and
a conductive structure extending along a first direction and arranged at intervals along a second direction, wherein the conductive structure is located on a side of the first semiconductor structure away from the second semiconductor structure, the conductive structure includes a plurality of first conductive structures coupled with the second semiconductor structure and a plurality of second conductive structures, the second conductive structures between adjacent ones of the first conductive structures and coupled to the first electrode plate, the first electrode plate is located between the second conductive structures and the plurality of capacitor structures, the first contact structure extends along a third direction and is located on a side of the first electrode plate along the first direction, and a first end and a second end of the first contact structure opposite to each other along the third direction are coupled with corresponding ones of the second conductive structures and the second semiconductor structure, and wherein the first direction and the second direction are both parallel to a surface of the first electrode plate, the third direction is perpendicular to the surface of the first electrode plate, and the first direction intersects the second direction; and
a controller configured to control the at least one semiconductor device.

14. A method for forming a semiconductor device, comprising:
forming a first semiconductor structure, wherein the first semiconductor structure includes a plurality of capacitor structures, a first electrode plate and a first contact structure, wherein the first electrode plate is coupled with the plurality of capacitor structures;
forming a second semiconductor structure;
bonding the first semiconductor structure and the second semiconductor structure; and
forming a conductive structure extending along a first direction and arranged at intervals along a second direction, wherein the conductive structure is located on a side of the first semiconductor structure away from the second semiconductor structure, the conductive structure includes a plurality of first conductive structures coupled with the second semiconductor structure and a plurality of second conductive structures, the second conductive structures between adjacent ones of the first conductive structures and coupled to the first electrode plate, the first electrode plate is located between the second conductive structures and the plurality of capacitor structures, the first contact structure extends along a third direction and is located on a side of the first electrode plate along the first direction, and a first end and a second end of the first contact structure opposite to each other along the third direction are coupled with corresponding ones of the second conductive structures and the second semiconductor structure; and
wherein the first direction and the second direction are parallel to a surface of the first electrode plate, the third direction is perpendicular to the surface of the first electrode plate, and the first direction intersects the second direction.

15. The method of claim 14, wherein, along the second direction, a sum of sizes of the plurality of first conductive structures is greater than or equal to a sum of sizes of all of the second conductive structures.

16. The method of claim 14, wherein the forming of the conductive structure includes:
forming, on the side of the first semiconductor structure away from the second semiconductor structure, a plurality of through holes exposing a part of the first electrode plate, wherein the plurality of through holes are arranged at intervals along the first direction;
filling the plurality of through holes with a first conductive material to form a plurality of conductive pillars;
forming, on the side of the first semiconductor structure away from the second semiconductor structure, a plurality of first trenches arranged at intervals along the second direction and a plurality of second trenches located between adjacent ones of the first trenches, wherein the first trenches and the second trenches extend along the first direction, and the second trenches expose surfaces of the conductive pillars; and
filling the plurality of first trenches and the second trenches with a second conductive material to respectively form a second conductive layer of the first conductive structures and a first conductive layer of the second conductive structures.

17. The method of claim 16, wherein along the second direction, a sum of sizes of the plurality of first trenches is greater than or equal to a sum of sizes of all of the second trenches.

18. The method of claim 17, wherein along the second direction, a ratio of the sum of sizes of the plurality of first trenches to a sum of sizes of all of the second trenches ranges from 1 to 2.

19. The method of claim 16, wherein:
along the third direction, a ratio of a size of one of the second trenches to a size of a through hole of the plurality of through holes ranges from 7 to 8; and
along the third direction, a ratio of the size of the one of the second trenches to a size of the first electrode plate ranges from 30 to 45.

20. The method of claim 14, wherein the forming of the first semiconductor structure further includes:
forming a vertical channel structure;
forming a gate structure on at least one side of the vertical channel structure;
forming a source and a drain, wherein the source and the drain are respectively located on opposite sides of the vertical channel structure along a thickness direction of the first electrode plate; and
forming a first capacitor structure of the plurality of capacitor structures, wherein the first capacitor structure is connected with one of the source or the drain.
